(19) United States
(12) Patent Application Publication
(10) Pub. No.: US 2012/0106254 A1
(43) Pub. Date: May 3, 2012

(54) MEMORY SYSTEM

(76) Inventors: Yuuta SANO, Yokohama-shi (JP); Toshifumi Watanabe, Yokohama-shi (JP)

(21) Appl. No.: 13/235,390

(22) Filed: Sep. 18, 2011

(30) Foreign Application Priority Data
Oct. 29, 2010 (JP) 2010-244659

(51) Int. Cl. G11C 16/06

(52) U.S. Cl. 365/185.18

(57) ABSTRACT

According to one embodiment, a memory system includes a NAND flash memory, a first unit, and an second unit. Memory cells capable of holding data and management data as a first control signal. Memory cells are arranged in a matrix in the NAND flash memory. The first unit holds a second and a third signal. The second signal is made variable in accordance with an output frequency. The third signal is made variable. The second unit outputs the data to an outside in accordance with the first to third signals. The second unit includes a buffer unit including first to third transistors. The output frequency includes a first frequency and a second frequency. If the first to third transistors output the data to the outside in synchronization with the second frequency, the first to third transistors may be turned on regardless of a value of the first control signal.

### CROSS-REFERENCE TO RELATED APPLICATIONS

This application is based upon and claims the benefit of priority from prior Japanese Patent Application No. 2010-244659, filed Oct. 29, 2010, the entire contents of which are incorporated herein by reference.

### FIELD

Embodiments described herein relate generally to, for example, a memory system that outputs data at a high clock frequency.

### BACKGROUND

The timing to read data from a semiconductor storage apparatus as an example of a memory system is decided by the frequency of a clock signal supplied from a host device connected to the semiconductor storage apparatus.

If, for example, a current driving force in an output buffer is small, data output is delayed with an increasing frequency of the clock signal.

### BRIEF DESCRIPTION OF THE DRAWINGS

FIG. 1 is an overall configuration example of a memory system according to an embodiment;

FIG. 2 is a configuration example showing a NAND flash memory according to an embodiment in detail;

FIG. 3 is a configuration example of a transfer gate and a block decoder according to an embodiment;

FIG. 4 is a configuration example showing a buffer controller according to an embodiment in detail;

FIG. 5 is a configuration example showing a data output buffer according to an embodiment in detail;

FIG. 6 is a conceptual diagram showing a rising waveform of a voltage in a node ADQ according to an embodiment;

FIG. 7 is a conceptual diagram showing a data output operation of synchronously (66 MHz, 83 MHz) and asynchronously reading from the memory system according to an embodiment;

FIG. 8 is a conceptual diagram showing the data output operation of synchronously (104 MHz) reading from the memory system according to an embodiment;

FIG. 9 is a configuration example showing details of the buffer controller according to a first modification of an embodiment;

FIG. 10 is a conceptual diagram showing the data output operation of synchronously (66 MHz, 83 MHz) and asynchronously reading from the memory system according to the first modification of an embodiment;

FIG. 11 is a conceptual diagram showing the data output operation of synchronously reading from the memory system according to the first modification of an embodiment;

FIG. 12 is an overall configuration example of the memory system according to a second modification of an embodiment;

FIG. 13 is a configuration example showing details of the buffer controller according to the second modification of an embodiment;

FIG. 14 is a conceptual diagram showing the data output operation from the memory system according to the second modification of an embodiment;

FIG. 15 is a conceptual diagram showing the data output operation from the memory system according to the second modification of an embodiment; and

FIG. 16 is a configuration example showing details of the buffer controller according to a third modification of an embodiment.

### DETAILED DESCRIPTION

An embodiment will be described below with reference to drawings. In the description that follows, common reference numerals are attached to common portions throughout all drawings.

### Embodiment

In general, according to one embodiment, a memory system includes a NAND flash memory, a first unit, and an second unit. Memory cells capable of holding data and management data as a first control signal in the NAND flash memory. The Memory cells are arranged in a matrix. The first unit holds a second control signal and a third signal. A value of the second control signal is made variable in accordance with an output frequency of the data. A value of the third control signal is made variable depending on whether the data is output synchronously with the output frequency or asynchronously. The second unit outputs the data read from the memory cells to an outside in accordance with the first to third control signals. The second unit includes a buffer unit including first to third transistors which each output the data to the outside in synchronization with the output frequency. The output frequency includes a first frequency and a second frequency higher than the first frequency. If the first to third transistors output the data to the outside in synchronization with the second frequency, the first to third transistors may be turned on regardless of a value of the first control signal.

A memory system according to the present embodiment includes a buffer capable of outputting data in accordance with the value of the frequency (hereinafter, referred to as the reading frequency) of a clock signal when outputting data to a host device. That is, the memory system includes a buffer portion that makes the rise and fall (current driving force) of data variable so that, when the reading frequency of data, that is, a clock signal is supplied from a host device, the reading frequency of the clock signal can be followed.

### <Overall Configuration>

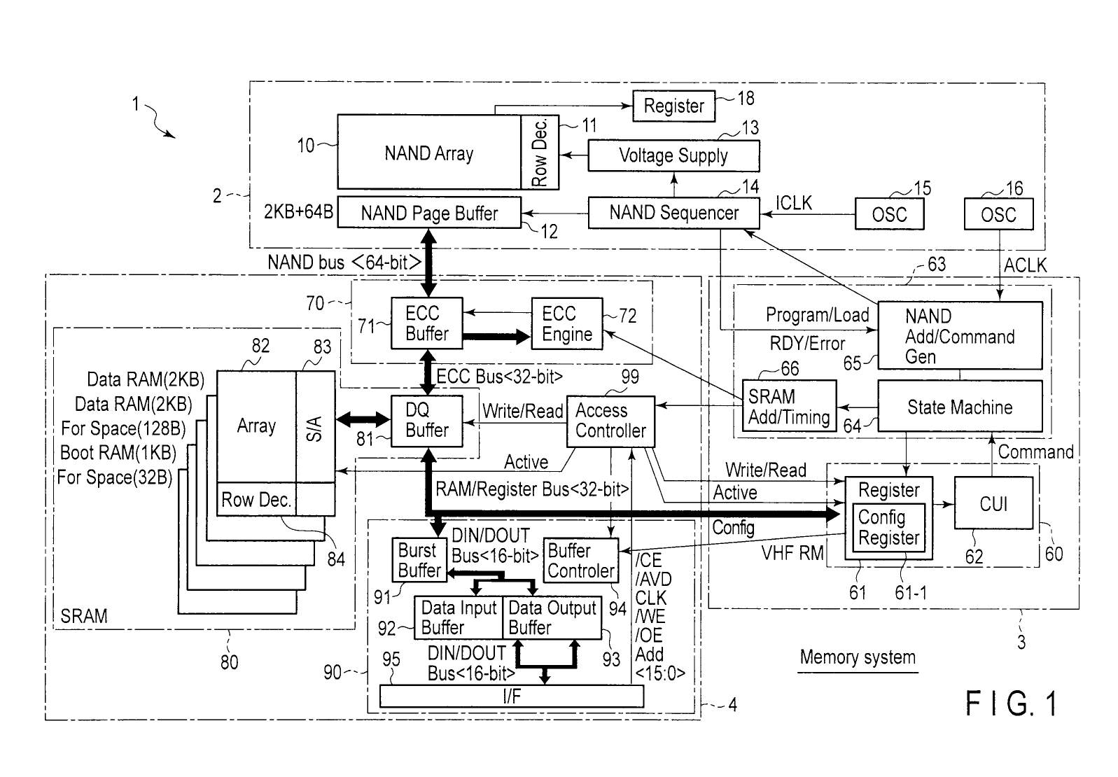

An overall configuration example of a memory system according to an embodiment will be described using FIG. 1. In the present embodiment, a semiconductor storage apparatus can be cited as an example of the memory system. The semiconductor storage apparatus includes, as a concrete configuration example, a NAND flash memory and an SRAM. That is, in the description that follows, a configuration including a NAND flash memory and an SRAM is defined as a memory system.

As illustrated in FIG. 1, a memory system 1 according to the present embodiment roughly includes a NAND flash memory 2, a control unit 3, and a RAM unit 4. The NAND flash memory 2, the control unit 3, and the RAM unit 4 are formed on the same semiconductor substrate and integrated as one chip. Details of each block will be described below.

### <NAND Flash Memory 2>

The NAND flash memory 2 functions as a main storage portion of the memory system 1. As shown in FIG. 1, the NAND flash memory 2 includes a memory cell array 10, a row decoder 11, a page buffer 12, a voltage generation circuit 13, a sequencer 14, oscillators 15, 16, and a register 18.

The memory cell array 10 includes a plurality of select transistors and memory cell transistors capable of holding data. Data is written (hereinafter, programmed) into the memory cell transistors, written data is read therefrom and further, written data is erased therefrom.

Each of the memory cell transistors is a MOS transistor having a laminated gate containing a charge accumulation layer and a control gate. A gate of the select transistor is connected to a select gate line and a control gate of the memory cell transistor is connected to a word line.

The memory cell array 10 also includes a plurality of blocks, which are sets of a plurality of memory cell transistors. The block is the unit of erasure. That is, data in the memory cell transistors contained in the same block is erased in one operation.

In addition to write data transferred from a host device (not shown), the memory cell array 10 holds on/off switching control signal data (hereinafter, referred to as an on/off switching control signal) described later. The on/off switching control signal data is a signal to switch the current supply capacity of a data output buffer portion by turning on or off MOS transistors with different gate widths in accordance with the reading frequency to read held data into the host device.

The row decoder 11 selects the word line and the select gate line for a programming, reading, or erasing operation of data. The row decoder 11 applies necessary voltages to the word line and the select gate line. Details of the memory cell array 10 and the row decoder 11 will be provided later.

The page buffer 12 is capable of holding page-size data and temporarily holds data provided from the RAM unit 4 to write the data into the memory cell array 10 during programming operation of data. During reading operation of data, on the other hand, the page buffer 12 temporarily holds data read from the memory cell array 10 and then transfers the data to the RAM unit 4.

The voltage generation circuit 13 generates a voltage necessary for programming, reading, or erasing data by stepping up or down the voltage provided from outside. The voltage generation circuit 13 supplies the generated voltage to, for example, the row decoder 11. The voltage generated by the voltage generation circuit 13 is applied to a word line WL.

The sequencer 14 controls the operation of the NAND flash memory 2 as a whole. That is, when a program instruction (Program), load instruction (Load), or erase instruction (not shown) is received from the control unit 3, the sequencer 14 performs a sequence for the execution of data programming, reading, or erasing in response thereto. Next, the sequencer 14 controls the operation of the voltage generation circuit 13 or the page buffer 12 according to the sequence.

The oscillator 15 generates an internal clock ICLK. That is, the oscillator 15 functions as a clock generator. The oscillator 15 supplies the generated internal clock ICLK to the sequencer 14. The sequencer 14 operates in synchronization with the internal clock ICLK.

The oscillator 16 generates an internal clock ACLK. That is, the oscillator 16 functions as a clock generator. The oscillator 16 supplies the generated internal clock ACLK to the control unit 3 and the RAM unit 4. The internal clock ACLK is a clock serving as a reference of the operation of the control unit 3 and the RAM unit 4.

The register 18 holds data of the on/off switching control signal described above. There are three kinds of the on/off switching control signal, which will be described later. That is, the register includes a region to hold these three kinds of signals. When the register 18 detects connection to an external host device and the start of power supply, the register 18 temporarily holds an on/off switching control signal and then transfers the signal to the RAM unit 4.

### <Details of the Configuration of the NAND Flash Memory 2>

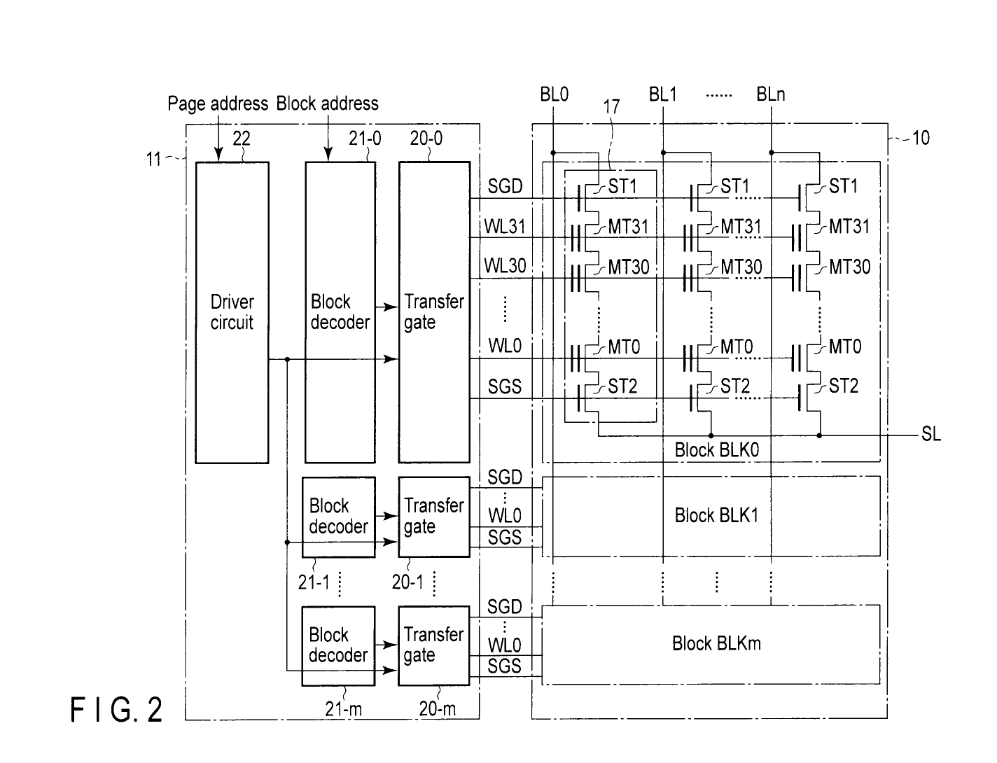

Next, a detailed configuration of the NAND flash memory 2 will be described by focusing on the memory cell array 10 and the row decoder 11. FIG. 2 is a circuit diagram of the memory cell array 10 and the row decoder 11.

### <<Details of the Memory Cell Array 10>>

First, the memory cell array 10 will be described. As shown in FIG. 2, the memory cell array 10 includes (m+1) (m is a natural number equal to 2 or greater) blocks BLK0 to BLKm. Hereinafter, if the blocks BLK0 to BLKm are not to be distinguished, the block is simply called the block BLK. Each of the blocks BLK includes a plurality of (n+1) (n+1 is a natural number equal to 2 or greater) memory cell units 17.

Each of the memory cell units 17 contains, for example, 32 memory cell transistors MT0 to MT31 and select transistors ST1, ST2. Hereinafter, if the memory cell transistors MT0 to MT31 are not to be distinguished, the memory cell transistor is simply called the memory cell transistor MT. The memory cell transistor MT includes a laminated gate structure having a charge accumulation layer (for example, a floating gate) formed on a semiconductor substrate via a gate dielectric film and a control gate formed on the charge accumulation layer via an inter-gate dielectric film. The number of memory cell transistors MT is not limited to 32 and may be 8, 16, 64, 128, 256 or the like and the number thereof is not to be limited. In the memory cell transistor MT, a dielectric film such as a nitride film is used as the charge accumulation layer and a MONOS (Metal Oxide Nitride Oxide Silicon) structure using a method of causing the nitride film to trap electrons may be adopted.

The memory cell transistors MT adjacent to each share the source and drain. The memory cell transistors MT are arranged between the select transistors ST1, ST2 in such a way that current paths thereof are connected in series. The drain on the side of one end of the memory cell transistors MT connected in series is connected to the source of the select transistor ST1 and the source on the side of the other end is connected to the drain of the select transistor ST2.

The control gates of the memory cell transistors MT in the same row are connected to one of word lines WL0 to WL31 in common. The gates of the select transistors ST1, ST2 in the same row are connected to select gate lines SGD, SGS in common respectively. For the simplification of description, the word lines WL0 to WL31 may simply be called the word line WL.

The drain of the select transistor ST1 is connected to one of bit lines BL0 to BLn. The bit lines BL0 to BLn connect a plurality of memory cell units 17 between a plurality of blocks BLK in common. If the bit lines BL0 to BLn are not to be distinguished, the bit line is simply called the bit line BL.

The source of the select transistor ST2 is connected to a source line SL. The source line SL is used in common inside the memory cell array 10. In the above configuration, data is written into a plurality of memory cell transistors MT connected to the same word line WL or read therefrom in one operation and this unit is called a page. Further, data is erased in one operation from a plurality of memory cell units 17 in the same row and this unit is the above block.

Each of the memory cell transistors MT can hold 1-bit data in accordance with, for example, a change in threshold voltage of the transistor based on the quantity of electrons injected into the charge accumulation layer. A configuration in which the control of the threshold voltage is subdivided and 2-bit data or more is held in each of the memory cell transistors MT may be adopted.

In each of the blocks BLK, a portion of the memory cell units 17 are used to hold, in addition to on/off switching control signal data, error correction information (such as a parity) and the remaining memory cell units 17 are used to hold user data. Incidentally, the on/off switching control signal data (management data) may be held in a management region provided inside the memory cell array 10.

Further, one of the blocks BLK (in the present embodiment, for example, the block BLKm) is used to hold system information of the NAND flash memory 2. An example of the system information is faulty block information. The faulty block information is information about the blocks BLK that are made unavailable for some failure and, for example, the block address thereof. Hereinafter, the block BLKm may be called a ROM fuse block.

### <<Details of the Row Decoder 11>>

Next, the row decoder 11 will be described further with reference to FIG. 2. As illustrated in FIG. 2, the row decoder 11 includes transfer gates 20-0 to 20-m, block decoders 21-0 to 21-m, and a driver circuit 22.

The driver circuit 22 is provided for the blocks BLK0 to BLKm in common. The driver circuit 22 decodes a page address to supply voltages to be applied to the word lines WL0 to WL31 and the select gate lines SGD, SGS to the transfer gates 20-0 to 20-m.

The block decoders 21-0 to 21-m are also provided corresponding to the blocks BLK0 to BLKm. The block decoders 21-0 to 21-m decode a block address to turn on or off the corresponding transfer gates 20-0 to 20-m.

The transfer gates 20-0 to 20-m are provided corresponding to the blocks BLK0 to BLKm. The transfer gates 20-0 to 20-m transfer the voltage provided from the driver circuit 22 to the word line WL and the select gate lines SGD, SGS of the corresponding block BLK. That is, one of the transfer gates 20-0 to 20-m is selected by the block decoder 21 and the voltage generated by the driver circuit 22 is transferred to the block BLK by the selected one of transfer gates 20-0 to 20-m. Which voltage to provide to which word line WL (that is, which word line WL to select) is selected by the block decoders 21-0 to 21-m. Hereinafter, the transfer gates 20-0 to 20-m may simply be called a transfer gate 70.

### <<Details of the Transfer Gate 20 and the Block Decoder 21>>

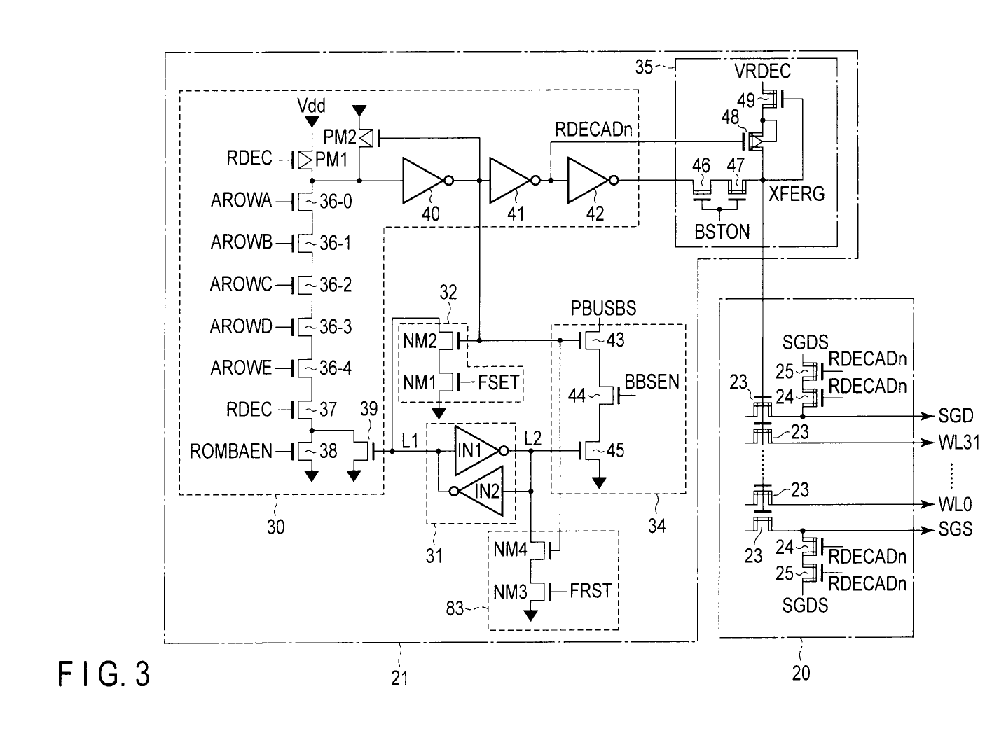

Next, details of the transfer gate 20 and the block decoder 21 will be described using FIG. 3. FIG. 3 is a circuit diagram of the transfer gate 20 and the block decoder 21.

First, the transfer gate 20 will be described. As illustrated in FIG. 3, the transfer gate 20 includes MOS transistors 23 to 25.

MOS transistor 23 is a high-voltage enhanced re-channel MOS transistor provided corresponding to each of the select gate lines SGD, SGS and the word lines WL0 to WL31. One end of the current path of MOS transistor 23 is connected to one corresponding line of the select gate lines SGD, SGS and the word lines WL0 to WL31 and a voltage is supplied to the other end by the driver circuit 22. The gates of MOS transistors 23 in the same transfer gate 20 are connected in common and are connected to a node XFERG of the corresponding block decoder 21. A signal RDECAD is provided from node XFERG. Signal RDECAD is made high when the corresponding block BLK is the selected block and made low when the corresponding block BLK is a non-selected block.

MOS transistors 24, 25 are high-voltage depressed n-channel MOS transistors and current paths thereof are connected in series. The source of MOS transistor 24 is connected to the select gate lines SGD, SGS, the drain of MOS transistor 25 is connected to a node SGDS, and a signal RDECADn is input into the gate of MOS transistor 25.

Signal RDECADn is an inverted signal of signal RDECAD. Therefore, the transfer gate 20 corresponding to the selected block transfers the voltage of the driver circuit 22 by MOS transistor 23 and the transfer gate 70 corresponding to a non-selected block transfer the voltage on node SGDS by MOS transistors 24, 25.

Next, the block decoder 21 will be described. As illustrated in FIG. 3, the block decoder 21 roughly includes a decoder unit 30, a holding unit 31, a set unit 32, a reset unit 33, a reading unit 34, and a level shifter 35.

The decoder unit 30 includes low-voltage enhanced p-channel MOS transistors PM1, PM2 whose withstand voltage is lower than that of the above high-voltage MOS transistors, low-voltage enhanced n-channel MOS transistors 36-0 to 36-4, 37 to 39, and inverters 40 to 42. MOS transistors PM1, PM2 have a power supply potential Vdd provided to the source thereof, the drains thereof are connected in common, and a signal RDEC is provided to the gate of MOS transistor PM1. MOS transistors 38, 39 have the sources thereof grounded, the drains thereof are connected in common, and a signal ROMBAEN is provided to the gate of MOS transistor 38. Signal ROMBAEN is normally low all the time. Current paths of MOS transistors 36-0 to 36-4, 37 are sequentially connected in series between the drains of MOS transistors PM1, PM2 and the drains of MOS transistors 38, 39. Signals ARROWA to ARROWS, and RDEC are input into the respective gates. If the block decoder 21 corresponds to the selected block, all signals ARROWA to ARROWE are made high. If the block decoder 21 does not correspond to the selected block, at least one of the signals is low. Signal RDEC is made high when signals ARROWA to ARROWE are input and made low before signals ARROWA to ARROWS are input. The inverters 40 to 42 are connected in series and an input node of the inverter 40 is connected to the sources of MOS transistors PM1, PM2 and the drain of MOS transistor 36-0. An output node of the inverter 40 and the input node of the inverter 41 are connected to the gate of MOS transistor PM2. The output of the inverter 41 becomes signal RDECADn.

The holding unit 31 is a latch circuit including inverters IN1, IN2. The input node of the inverter IN1 and the output node of the inverter IN2 are connected to a node L1 and the input node of the inverter IN2 and the output node of the inverter IN1 are connected to a node L2. Node L1 is connected to the gate of MOS transistor 39. The holding unit 31 holds faulty block information when data is loaded or programmed or during normal erasing operation (erasing operation for which the number of blocks to be erased is one). One timing when faulty block information is stored in the holding unit 31 is at power-on of the memory system 1. That is, faulty block information is read from the ROM fuse block (block BLKm) based on instructions of the control unit 3 at power-on and the information is held in the holding unit 31. More specifically, nodes L1 in the holding units 31 of all the block decoders 21 are made high by a signal FRST of the reset unit 33 described later being made high. Subsequently, a signal FSET is made high while only the block decoders 21 corresponding to faulty blocks are selected. As a result, nodes L1 are made low in the corresponding block decoders 21. From the foregoing, when the holding unit 31 holds faulty block information, node L1 is made low and otherwise, node L1 is made high.

The set unit 32 includes low-voltage enhanced n-channel MOS transistors NM1, NM2. The source of MOS transistor NM1 is grounded and signal FSET is input into the gate thereof. MOS transistor NM2 has the source connected to the drain of MOS transistor NM1, the drain connected to node L1, and the gate connected to the output node of the inverter 40.

The reset unit 33 includes low-voltage enhanced n-channel MOS transistors NM3, NM4. The source of MOS transistor NM3 is grounded and signal FRST is input into the gate thereof. MOS transistor NM4 has the source connected to the drain of MOS transistor NM3, the drain connected to node L2, and the gate connected to the output node of the inverter 40.

The reading unit 34 includes low-voltage enhanced n-channel MOS transistors 43 to 45. Current paths of MOS transistors 43 to 45 are sequentially connected in series between a node PBUSBS and a ground potential node. The gate of MOS transistor 43 is connected to the output node of the inverter 40, a signal BBSEN is input into the gate of MOS transistor 44, and the gate of MOS transistor 45 is connected to node L2. Node PBUSBS is connected between each block decoder 21 in common.

The level shifter 35 includes MOS transistors 46 to 49. MOS transistor 46 is a low-voltage depressed n-channel MOS transistor, has the drain connected to the output node of the inverter 42, and has the gate provided with a signal BSTON. Signal BSTON is made high while a block address is decoded. MOS transistor 47 is a depressed n-channel MOS transistor whose withstand voltage is higher than the withstand voltage of MOS transistor 46. MOS transistor 47 has the drain connected to the source of MOS transistor 46, has the drain connected to node XFERG, and has the gate provided with signal BSTON. MOS transistor 48 is an enhanced p-channel MOS transistor of the high-voltage type. MOS transistor 48 has the drain connected to node XFERG, has the source connected to a back gate, and has the gate into which signal RDECADn is input. MOS transistor 49 is a depressed n-channel MOS transistor of the high-voltage type. MOS transistor 49 has the drain provided with a voltage VRDEC, has the source connected to the source of MOS transistor 48, and has the gate connected to node XFERG. Voltage VRDEC is a value needed for writing, reading, or erasing data. Node XFERG is connected to the gate of MOS transistor 23 in the corresponding transfer gate 20. Therefore, the potential of the high signal RDECAD becomes a value in accordance with voltage VRDEC.

In the block decoder 21 in the above configuration, if the corresponding block BLK matches the block address, MOS transistors 36-0 to 36-4 are set to an on-state signal RDECADn is made low (RDECAD=High). As a result, node XFERG is provided with voltage VRDEC. Thus, MOS transistor 23 is turned on in the corresponding transfer gate 20.

On the other hand, if the corresponding block BLK does not match the block address, at least one of MOS transistors 36-0 to 36-4 is turned off and signal RDECADn is made high. As a result, MOS transistor 23 is turned off in the corresponding transfer gate 20.

If node L1 is made low by the holding unit 31 regardless of the block address, MOS transistor 39 is turned off. As a result, signal RDECADn is made high and MOS transistor 23 is turned off in the corresponding transfer gate 20.

### <Control Unit 3>

Next, returning to FIG. 1, the control unit 3 will be described. The control unit 3 controls the operation of the NAND flash memory 2 and the RAM unit 4. That is, the control unit 3 has a function to control the operation of the memory system 1 as a whole. As illustrated in FIG. 1, the control unit 3 includes an internal register 60 (internal register in FIG. 1) and a state machine for memory system 63.

The internal register 60 includes a register 61 (register in FIG. 1) and a command user interface (CUI in FIG. 1) 62. Further, the register 61 includes a Config register 61-1. Config data described later is a data sequence transferred from an external host device and more specifically, contains information such as the reading frequency when data is read from the NAND flash memory 2.

The state machine for memory system 63 includes a state machine (state machine in FIG. 1) 64, an address/command generation circuit (NAND Add/Command Gen in FIG. 1) 65, and an address/timing generation circuit (SRAM Add/Timing in FIG. 1) 66.

The register 61 is a register to set/hold the operating state of the memory system 1. More specifically, the Config register 61-1 holds Config data provided by a host device via an interface 90 described later. That is, the reading frequency of data synchronized with a clock signal output from a data output buffer 93 is held. More specifically, the Config register 61-1 holds frequency information contained in the Config data and values of very High throughput (VHF) and (read mode RM), which are variable in accordance with the frequency information.

RM takes the value of “0” or “1” and takes “0” when data is read asynchronously and “1” when data is read synchronously. Reading data asynchronously means that read data is output from an interface 95 without being synchronized with a clock signal. More specifically, if, for example, a read command is supplied from a host device, read data of, for example, only one page is output from the interface 95 via the NAND page buffer 12 and an SRAM 80 without being synchronized with a clock signal and such a case is called asynchronous reading. Reading data synchronously, by contrast, means that a data sequence is read by being synchronized with a clock signal. If VHF takes a value or “0” or “1” and the reading frequency is 104 MHz for burst read, the value of VHF is set to “1”. If the frequency is other than 104 MHz (for example, asynchronous reading or synchronous reading and the frequency is 66 MHz, 83 MHz), the value of VHF is set to “0”.

The register 61 sets the operating state of a function in accordance with a register write command or register read command. More specifically, a load command is set in the register 61 for loading data and a program command is set for programming data. The register write command or register read command is a write command or read command (Write/Read) for the register 61 from an access controller 99. Loading is an operation that reads data from the NAND flash memory 2 and outputs the data to the SRAM 80, programming is an operation of data in the SRAM 80 being transferred to the page buffer 12 until the data is written into the memory cell array 10 of the NAND flash memory 2, and erasing is an operation to erase data inside the NAND flash memory 2.

A command user interface 62 supplies the values of VHS and RM held by the register 61 to a burst controller 94 described later. Further, the command user interface 62 recognizes that a function execution command is provided to the memory system 1 by a predetermined command being set in the register 61. Then, the command user interface 62 issues an internal command signal (Command) to the state machine 64.

The state machine 64 controls a sequence operation inside the memory system 1 based on an internal command signal provided from the command user interface 62. There are many functions supported by the state machine 64 such as loading, programming, and erasing and the state machine 64 controls the operation of the NAND flash memory 2 and the RAM unit 4 to execute the functions.

The address/command generation circuit 65 controls the operation of the NAND flash memory 2 based on the control of the state machine 64. More specifically, the address/command generation circuit 65 generates addresses and commands (Program/Load/Erase) and outputs the addresses and commands to the NAND flash memory 2. The address/command generation circuit 65 outputs these addresses and commands while being synchronized with the internal clock ACLK generated by the oscillator 16.

The address/timing generation circuit 66 controls the operation of the RAM unit 4 based on the control of the state machine 64. More specifically, the address/timing generation circuit 66 issues addresses and commands needed for the RAM unit 4 and outputs the addresses and commands to the access controller 99 and an ECC engine 72.

### <RAM Unit 4>

Next, the RAM unit 4 will be described. The RAM unit 4 includes an ECC unit 70, the static random access memory (SRAM) 80, the interface unit 90 (PAD described later), and the access controller 99.

In the memory system 1 according to the present embodiment, the NAND flash memory 2 functions as a main storage unit and the SRAM 80 of the RAM unit 4 functions as a buffer (secondary cache). Therefore, when a load command is received from the address/command generation circuit 65, the sequencer 14 reads data from the NAND flash memory 2. That is, data read from the memory cell array 10 of the NAND flash memory 2 is stored in the SRAM 80 of the RAM unit 4 via the page buffer 12. Then, data in the SRAM 80 is transferred to the interface unit 90 and, as a result, output to the host device (not shown).

On the other hand, when the sequencer 14 receives a program command from the address/command generation circuit 65 and causes the NAND flash memory 2 to store data, the data provided from the host device is first stored in the SRAM 80 in the RAM unit 4 via the interface unit 90. Then, the data in the SRAM 80 is transferred to the page buffer 12 and written into the memory cell array 10.

The operation until data in the SRAM 80 is transferred to the interface 95 via a burst buffer 91 and the data output buffer 93 described later in the interface unit 90 is called “read” of data. Data transferred from the burst buffer 91 to the data output buffer 93 and data output from the data output buffer 93 to the interface 95 are called Dout, which is 16-bit parallel output. That is, as will be described later, 16 output terminals of the data output buffer 93 are provided.

Further, the operation until data the NAND flash memory 2 should be caused to store is transferred to the SRAM 80 from the interface 95 via a data input buffer 92 and the burst buffer 91 is called “write” of data. Data transferred from the interface 95 to the data input buffer 92 and data transferred from the data input buffer 92 to the burst buffer 91 are called Din, which is also 16-bit parallel input.

Each configuration of the ECC unit 70, the SRAM 80, the interface unit 90, and the access controller 99 will be described below.

### <<ECC Unit 70>>

The ECC unit 70 detects errors of data, corrects errors of data, and generates parity for data (hereinafter, the above processing may be called ECC processing together). That is, when data is loaded, the ECC unit 70 detects and corrects errors of data read from the NAND flash memory 2. On the other hand, when data is programmed, the ECC unit 70 generates parity for the data to be programmed. The ECC unit 70 includes an ECC buffer 71 and the ECC engine 72.

The ECC buffer 71 is connected to the page buffer 12 of the NAND flash memory 2 by a NAND bus and connected to the SRAM 80 by an ECC bus. These buses have the same bus width and have, for example, a 32-bit width. When data is loaded, the ECC buffer 71 holds data transferred from the page buffer 12 via the NAND bus and also transfers ECC processed data to the SRAM 80 via the ECC bus. On the other hand, when data is programmed, the ECC buffer 71 holds data transferred from the SRAM 80 via the ECC bus and also transfers transferred data and parity therefor to the page buffer 12 via the NAND bus.

The ECC engine 72 performs ECC processing by using data held in the ECC buffer 71. The ECC engine 72 uses, for example, a 1-bit correction method using Hamming code. The ECC engine 72 generates a syndrome by using parity when data is loaded, thereby detecting errors. When an error is detected, the error is corrected. On the other hand, parity is generated when data is programmed.

### <<SRAM 80>>

Next, the SRAM 80 will be described. In the memory system 1, the SRAM 80 functions as a buffer memory for the NAND flash memory 2. As illustrated in FIG. 1, the SRAM 80 includes a DQ buffer 81, a plurality (two in the present embodiment) of data RAMs, one spare data RAM (for spare in FIG. 1), one boot RAM, and one spare boot RAM (boot RAM in FIG. 1).

The DQ buffer 81 temporarily holds data when the data is written into the data RAM and the boot RAM or data is read from the data RAM and the boot RAM. As described above, the DQ buffer 81 can transfer data to and from the ECC buffer 71 by the ECC bus. The DQ buffer 81 can also transfer data to and from the interface unit 90 by using, for example, a RAM/register bus having a 32-bit bus width. Like the page buffer 12, the DQ buffer 81 also includes a region to hold main data and a region to hold parity and the like.

The boot RAM temporarily holds, for example, boot code for activating the memory system 1. The capacity of the boot RAM is, for example, 1 KB. The data RAM temporarily holds boot code, protect information and the like, the capacity thereof is, for example, 2 KB, and two data RAMs are provided. Each of these RAMs includes a memory cell array 82, a sense amplifier 83, and a row decoder 84. The spare data RAM functions as a spare region when a holding region of the data RAM is faulty and data cannot be held. This also applies to the spare boot RAM. That is, the spare boot RAM functions as a spare region when a holding region of the boot RAM is faulty and data cannot be held.

The memory cell array 82 includes a plurality of SRAM cells capable of holding data. Each of SRAM cells is connected to a word line and a bit line. The sense amplifier 83 senses and amplifies data read from SRAM cells to bit lines. The sense amplifier 83 also functions as a load when data in the DQ buffer 81 is written into SRAM cells. The row decoder 84 selects the word line in the memory cell array 82.

### <<Access Controller 99>>

The access controller 99 receives a control signal and an address from the interface 95. The access controller 99 controls the SRAM 80 and the control unit 3 so that an operation satisfying host device requests is performed. More specifically, the access controller 99 activates one of the SRAM 80 and the internal register 60 described later of the control unit 3 in accordance with a host device request.

Next, the access controller 99 issues a write command or read command of data for the SRAM 80 or a write command or read command of data for the register 61. With the above control, the SRAM 80 or the control unit 3 starts the operation thereof.

### <<Interface Unit 90>>

The interface unit 90 includes, for example, one burst buffer (or a plurality of, for example, two burst buffers) 91, the data input buffer 92 (data input buffer), the data output buffer 93 (data output buffer), the buffer controller 94 (buffer controller), and the interface 95.

The burst buffer 91 can transfer data to each of the DQ buffer 81 and the control unit 3 by the RAM/register bus and also can transfer data to the interface unit 95 via the data input/output buffers 92, 93 by DIN/DOUT buses having, for example, a 16-bit bus width. The DIN/DOUT buses have each a 16-bit bus width. That is, data in the burst buffer 91 is output to a host device via the data output buffer 93 and the interface 95 when data is read and data provided by a host device is transferred to the burst buffer 91 via the interface 95 and the data input buffer 92 when data is written.

The burst buffer 91 temporarily holds data provided from a host device outside the memory system 1 via the interface 95 or data provided from the DQ buffer 81. In the present embodiment, as an example, Config data supplied from a host device is such data. The burst buffer 91 transfers the Config data to the register 61 described later by using the RAM/register bus. As described above, the Config data contains information (reading frequency) indicating at which frequency the host device should read data.

The data input buffer 92 connects the burst buffer 91 and the interface 95 by a Din bus. As described above, data supplied from a host device via the interface 95 is called Din and the Din is input as 16-bit parallel data.

The data outputs buffer 93 connects the burst buffer 91 and the interface 95 by a Dout bus. The data output buffer 93 also includes a configuration that makes the current supply capacity to the output pad (PAD) variable in accordance with the reading frequency of a clock signal supplied from the host device. A detailed configuration thereof will be provided later.

The buffer controller 94 controls the data output buffer 93 in accordance with VHF and RM received from the register 61. A detailed configuration of the buffer controller 94 will be provided later.

The interface 95 can be connected to a host device and controls input/output of data, control signals, and various signals such as the address Add to and from the host device. Examples of the control signals include a chip enable signal/CE to enable the whole memory system 1, an address valid signal/AVD to latch an address, a burst read clock signal, a write enable signal/WE to enable a write operation, and an output enable signal/OE to enable output of data to the outside.

The interface 95 is connected to the burst buffer 91 via the data input buffer 92 and the data output buffer 93.

The interface 95 transfers a control signal of a read request, load request, write request, program request or the like of data from a host device to the access controller 99.

### <Detailed Configuration of the Buffer Controller 94 and the Data Output Buffer 93>

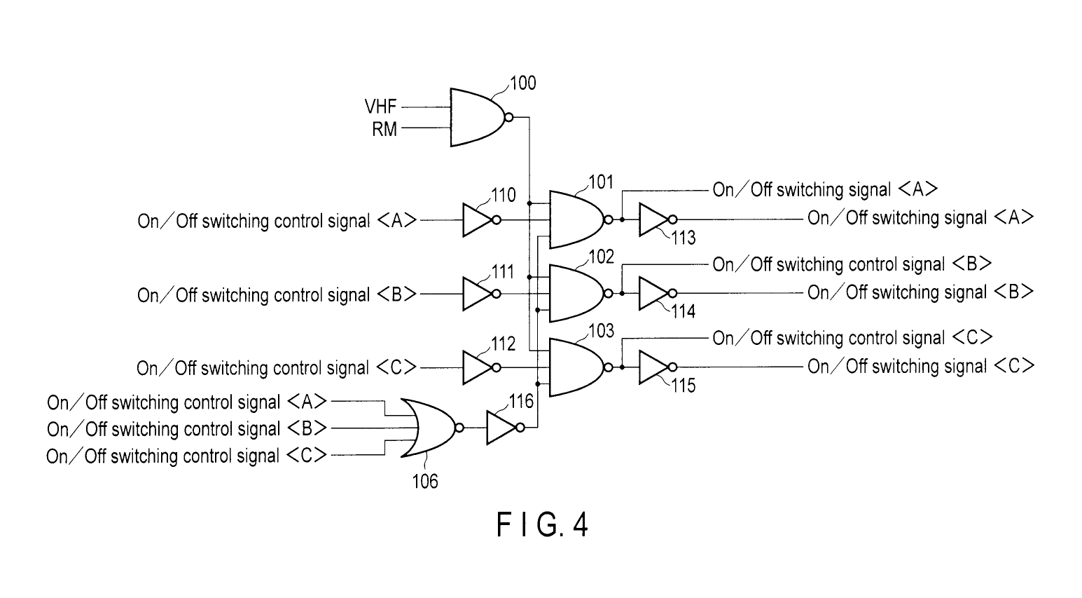

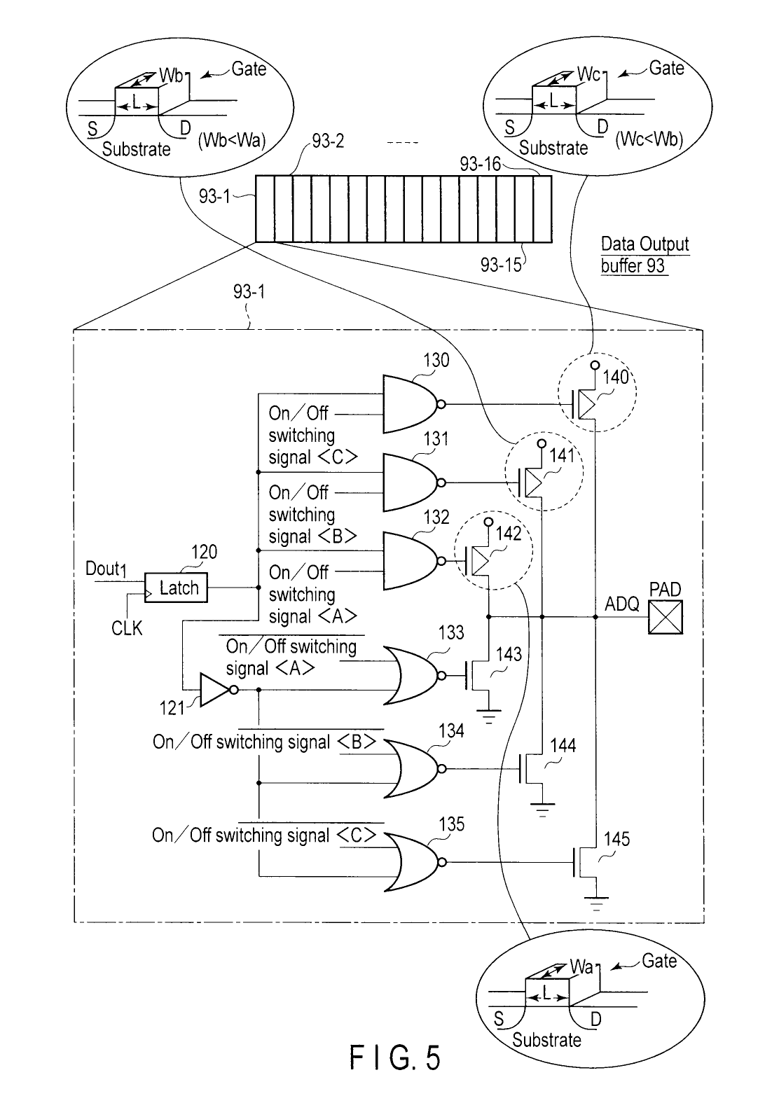

Next, the detailed configuration of the buffer controller 94 and the data output buffer 93 will be described using FIGS. 4 and 5.

First, the buffer controller 94 will be described using FIG. 4. As shown in FIG. 4, the buffer controller 94 includes NAND gates 100 to 103, inverters 110 to 116, and a NOR gate 106.

As shown in FIG. 4, NAND gate 100 performs a NAND operation of VHF and RM. The operation result is supplied to NAND gates 101 to 103. The NOR gate 106 performs a NOR operation of on/off switching control signals <A> to <C> (denoted as on/off switching control signal in FIG. 4). The operation result is inverted by the inverter 116 and an inverted result is supplied to each of NAND gates 101 to 103.

The inverter 110 inverts input on/off switching control signal <A> and supplies an inversion result thereof (/on/off switching control signal <A>) to NAND gate 101.

NAND gate 101 performs a NAND operation of signals from NAND gate 100, the inverter 110, and the inverter 116 and outputs a result thereof to the inverter 113. A signal output from NAND gate 101 is defined as an on/off switching signal <A> and a signal output from the inverter 113 is defined as an /on/off switching signal <A> (denoted as on/off switching signal <A> in FIG. 4). This applies similarly to an on/off switching signal <B>, an /on/off switching signal <B>, an on/off switching signal <C>, and an /on/off switching signal <C> output from NAND gates 102, 103 and the inverters 114, 115 (denoted as on/off switching signal <B> and on/off switching signal <C> in FIG. 4). That is, on/off switching signal <B> is obtained as a result of a NAND operation of signals from NAND gate 100, the inverter 111, and the inverter 116 by NAND gate 102. Similarly, on/off switching signal <C> is obtained as a result of a NAND operation of signals from NAND gate 100, the inverter 112, and the inverter 116 by NAND gate 103.

As described above, values of on/off switching control signals <A> to <C>, that is, management data, are held by the management region of the memory cell array 10. That is, the on/off switching control signals read from the management region once and then stored in the register 18 are supplied to the buffer controller 94. These values take one of values of “0” and “1” and there are eight patterns of “0”, “0”, “0” to “1”, “1”, “1” of cases in which on/off switching control signal <A>, on/off switching control signal <B>, and on/off switching control signal <C> each take one of these values. As will be described later, on/off switching control signals <A> to <C> are signals that control on/off of the corresponding MOS transistors.

Next, a detailed configuration of the data output buffer 93 will be described using FIG. 5. As shown in FIG. 5, the data output buffer 93 includes buffer units 93-1 to 93-16. This is because, as described above, the 16-bit Dout is output from the data output buffer 93 in parallel. Douts input into the buffer units 93-1 to 93-16 are defined as Dout₁ to Dout₁₆. The internal configuration of each of the buffer units 93-1 to 93-16 is the same and thus, as an example, the buffer unit 93-1 is selected for the description. FIG. 5 shows an enlarged view of the buffer unit 93-1.

As shown in FIG. 5, the buffer unit 93-1 includes a latch circuit (Latch in FIG. 5) 120, NAND gates 130 to 132, NOR gates 133 to 135, p-channel MOS transistors 140 to 142, and n-channel MOS transistors 143 to 145.

The latch circuit 120 outputs Dout₁ supplied from the burst buffer 91 to NAND gates 130 to 132 and the NOR gates 133 to 135 in synchronization with a clock signal (CLK in FIG. 5) supplied from a host device. More specifically, Dout₁ is output in timing when the clock signal is made high. Thus, Dout₁ output from the latch circuit 120 is output faster with an increasing frequency of the clock signal.

NAND gate 132 performs a NAND operation of the Dout₁ and on/off switching signal <A> and supplies the operation result to the gate of MOS transistor 142.

The NOR gate 133 performs a NOR operation of the Dout₁ and /on/off switching signal <A> and supplies the operation result to the gate of MOS transistor 143. For example, a voltage VDD is supplied to the current path (source end) of MOS transistor 142 and the other end (drain end) is connected to node ADQ. One end (drain end) of the current path of MOS transistor 143 is connected to node ADQ in common with the drain end of MOS transistor 142 and the other end (source end) is grounded. The voltage value of node ADQ is transferred to the interface 95 via the output PAD. At this point, MOS transistors 142, 143 are not turned on at the same time.

NAND gate 131 performs a NAND operation of the Dout₁ and on/off switching signal <B> and supplies the operation result to the gate of MOS transistor 141.

The NOR gate 134 performs a NOR operation of the Dout₁ and/on/off switching signal <B> and supplies the operation result to the gate of MOS transistor 144. For example, voltage VDD is supplied to the current path (source end) of MOS transistor 141 and the other end (drain end) is connected to node ADQ. One end (drain end) of the current path of MOS transistor 144 is connected to node ADQ in common with the drain end of MOS transistor 141 and the other end (source end) is grounded. The voltage value of node ADQ is transferred to the interface 95 via the output PAD. Like MOS transistors 142, 143, MOS transistors 141, 144 are not turned on at the same time from the above reason. The gate width of MOS transistor 141 is set to, for example, Wb (<Wa).

Further, NAND gate 130 performs a NAND operation of the Dout₁ and on/off switching signal <C> and supplies the operation result to the gate of MOS transistor 140. The NOR gate 135 performs a NOR operation of the Dout₁ and /on/off switching signal <C> and supplies the operation result to the gate of MOS transistor 145. For example, voltage VDD is supplied to the current path (source end) of MOS transistor 140 and the other end (drain end) is connected to node ADQ. One end (drain end) of the current path of MOS transistor 145 is connected to node ADQ in common with the drain end of MOS transistor 140 and the other end (source end) is grounded. The voltage value of node ADQ is transferred to the interface 95 via the output PAD. Like MOS transistors 142, 143, MOS transistors 140, 145 are not turned on at the same time from the above reason. The gate width of MOS transistor 140 is set to, for example, We (<Wb).

That is, from the foregoing, the amount of current flowing into node ADQ is made variable in accordance with the number of MOS transistors in the on state among MOS transistors 140 to 143. In other words, with an increasing frequency of the clock signal, the MOS transistor with an increasing gate width is turned on or all MOS transistors 140 to 143 are turned on.

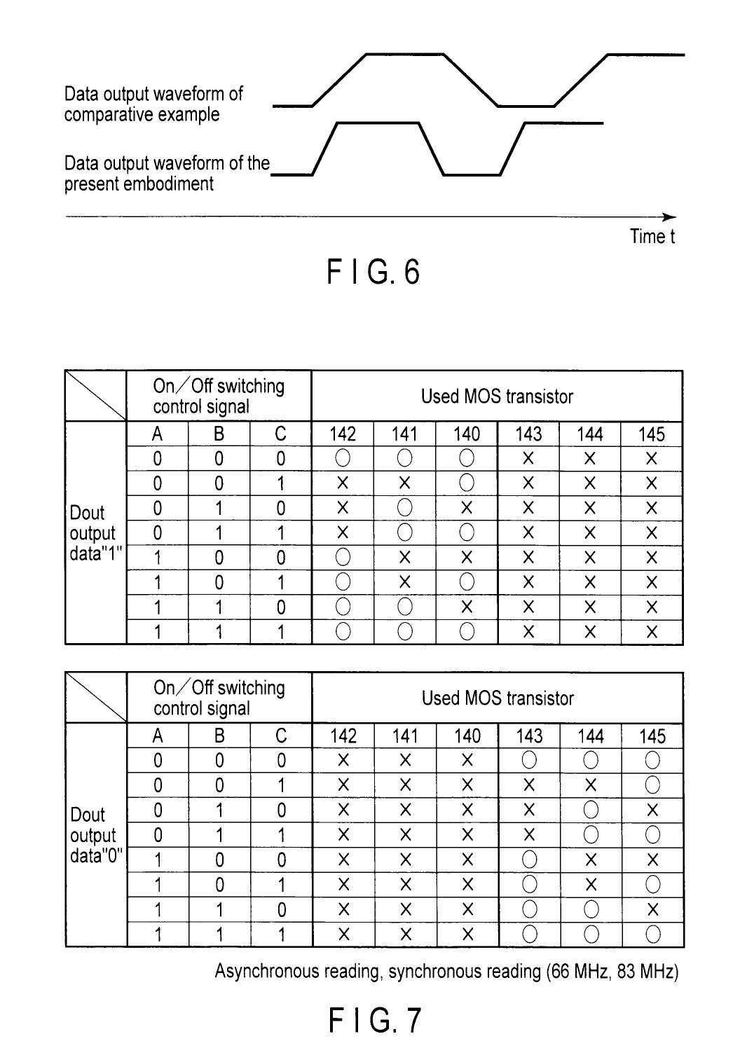

A concrete example in which all MOS transistors 140 to 143 are turned on is a case when data output from node ADQ is read at 104 MHz of the frequency of the clock signal. In this case, the rise time (angle) to reach a desired voltage value from, for example, 0 [V] in the potential on node ADQ is assumed to be steep. This situation will be described using FIG. 6.

FIG. 6 is a conceptual diagram showing voltage rises on node ADQ of the buffer unit 93-1 in the present embodiment and the comparative example. As shown in FIG. 6, compared with the comparative example, the rise time (angle) of the voltage on node ADQ in the present embodiment is steep and the rise time thereof is a short time t1 which is shorter than in the comparative example (t2). This is because MOS transistors 140 to 142 with different gate widths are all turned on, that is, the current supply capacity is increased to a maximum to increase the amount of current flowing into node ADQ per unit time.

An example in which MOS transistors 142, 143 in FIG. 5 are controlled using on/off switching signal <A> will be described below as an example.

A case when the value of Dout₁ output from the latch circuit 120 is “1”, that is, high, and the value of on/off switching signal <A> is “1”, that is, high will be considered. In this case, each of NAND gate 132 and the NOR gate 133 outputs a low signal. As a result, MOS transistor 142 is turned on and MOS transistor 143 is turned off. The low output from NAND gate 132 is below the threshold voltage Vtha held by MOS transistor 142.

Thus, voltage VDD supplied to the source end of MOS transistor 142 flows into node ADQ to be transferred to voltage PAD. The voltage on node ADQ is made high in accordance with the output timing of Dout₁. Moreover, as described above, MOS transistor 143 is in the off state when Dout₁ is output (when MOS transistor 142 is turned on).

MOS transistors 140, 141, 144, 145 are also controlled in the same manner by using on/off switching control signals <B>, <C> and thus, a description thereof is omitted.

### <Operation of the Memory System 1>

Next, a rough operation of the memory system 1 in the above configuration will briefly be described. In the memory system 1 according to the present embodiment, as described above, data is exchanged between the NAND flash memory 2 and a host device via the SRAM 80.

That is, when a host device causes the NAND flash memory 2 of the memory system 1 to store data, first data is temporarily stored in the data RAM or boot RAM according to a write command and the address of the SRAM 80 provided from the host device. Then, the data stored in the SRAM 80 is programmed into the NAND flash memory 2 in units of pages according to a program command and the address of the NAND flash memory 2 provided from the host device.

When a host device reads data from inside the NAND flash memory 2, first data is read from the NAND flash memory 2 according to a load command, the address of the NAND flash memory 2, and the address of the SRAM 80 provided from the host device and then temporarily stored in the data RAM or boot RAM. Subsequently, the data held in the data RAM or boot RAM is read by the host device via the interface unit 90 according to a read command and the address of the SRAM 80 provided from the host device.

An example of the procedure when the operation is loading will be described below.

First, a host device inputs the address of the NAND flash memory 2 to load and the address of the SRAM and also inputs a load command for the interface unit 90.

Then, in the memory system 1, the access controller 99 sets the above addresses and command to the register 61. The command user interface 62 that recognizes that a command has been set in the register 61 issues an internal command signal. For the loading, a load command is issued.

With the reception of the load command from the command user interface 62, the state machine 64 is activated. After necessary initialization of each circuit block, the state machine 64 makes a request of the address/command generation circuit 65 to issue a sense command to the NAND flash memory 2.

Then, the address/command generation circuit 65 issues a sense command to the sequencer 14 to sense data based on the address set in the register 61.

With the reception of the sense command from the address/command generation circuit 65, the sequencer 14 is activated. After necessary initialization in the NAND flash memory 2, the sequencer 14 performs a sensing operation of the specified address. That is, the sequencer 14 controls the voltage generation circuit 13, the row decoder 11, a sense amplifier (not shown), and the page buffer 12 to cause the page buffer 12 to store sense data. Then, the sequencer 14 notifies the state machine 64 of the end of the sensing operation.

Next, the state machine 64 instructs the address/command generation circuit 65 to issue a transfer command to the NAND flash memory 2. The transfer command is an instruction to transfer data from the NAND flash memory 2 to the RAM unit 4. In response to this instruction, the address/command generation circuit 65 issues and outputs a transfer command to the sequencer 14.

The sequencer 14 that has received the transfer command sets the page buffer 12 so that data can be transferred. Data in the page buffer 12 is transferred to the ECC buffer 71 via the NAND bus according to the control of the sequencer 14.

Further, the state machine 64 issues an error correction start control signal to the ECC unit 70. In response to this signal, the ECC unit 70 performs ECC processing. ECC-processed data is transferred from the ECC unit 70 to the DQ buffer 81 via the ECC bus.

Subsequently, data in the DQ buffer 81 is written into the memory cell array 82 of the SRAM 80 according to the instruction of the access controller 99.

With the above processing, loading of data is completed. Then, when a read command is issued by the host device via the interface unit 90, 16-bit data (Dout₁ to Dout₁₆) is transferred from the memory cell array 82 in the DQ buffer 81 to the burst buffer 91 in the interface 90 via the RAM/register bus.

Subsequently, Dout₁ to Dout₁₆ supplied from the burst buffer 91 are output to the external host device from the interface 95 in accordance with on/off switching control signals <A>to <C>issued by the buffer controller 94.

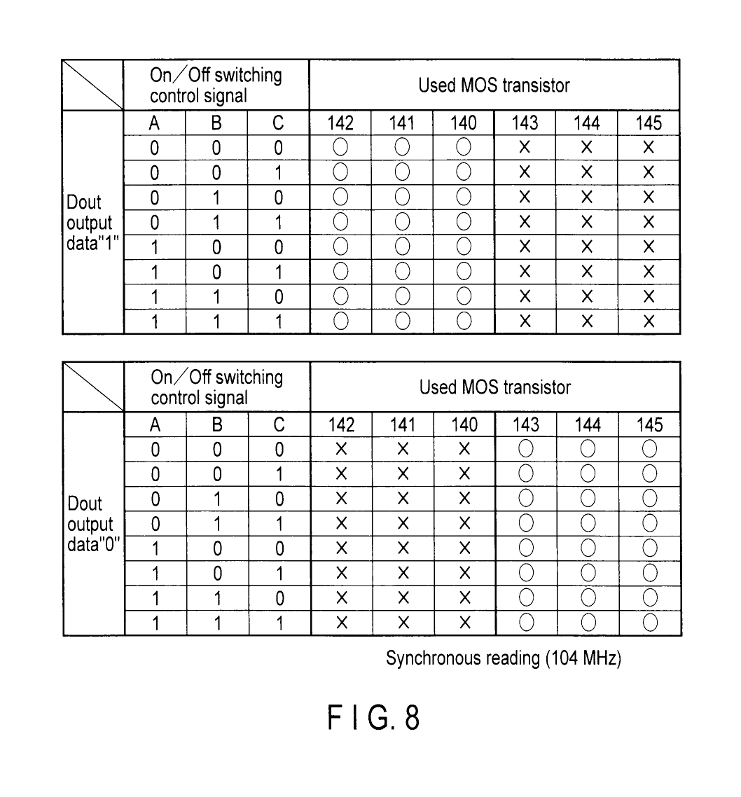

Detailed operations of the buffer controller 94 and the data output buffer 93 will be described below using FIGS. 7 and 8.

### <Operation of the Interface 90>

Next, the data output operation of the interface 90 to output Dout that has reached the burst buffer 91 as described above will be described using FIGS. 7 and 8. More specifically, the output operation of Dout₁ to Dout₁₆ by the data output buffer 93 will be described. FIG. 7 is a conceptual diagram showing the on/off states of MOS transistors 140 to 145 when the output (“0” output, “1” output) of Dout₁ to Dout₁₆ is asynchronous or synchronous and the reading frequency of a clock signal is 66 MHz or 83 MHz.

In FIG. 7, data (“0” or “1”) that can be taken by on/off switching control signals <A> to <C> and the on/off states of MOS transistors 140 to 145 are shown. As described above, VHF=“0/1” and RM=“0” are set for asynchronous reading. For synchronous reading at 66 MHz or 83 MHz of the frequency of a clock signal, VHF=“0” and RM=“1” are set. In both cases, as shown in FIG. 7, MOS transistors 140 to 145 are turned on or off according to the values of on/off switching control signals <A> to <C>.

That is, if, for example, on/off switching control signal <A>=“1” when Dout₁=1 (high), the corresponding MOS transistor 142 is turned on. This also applies to on/off switching control signal <B> and on/off switching control signal <C>. That is, to turn all MOS transistors 140 to 142 on, the respective values of on/off switching control signals <A> to <C> may be set to “1”. Incidentally, even when the values of on/off switching control signals <A> to <C> are all set to “0”, MOS transistors 140 to 142 are all turned on. MOS transistors 143 to 145 are all turned off regardless of the values of on/off switching control signals <A> to <C>.

When Dout₁=0, there is no data output and thus, MOS transistors 140 to 142 are all turned off regardless of the values of on/off switching control signals <A> to <C>. In contrast, MOS transistors 143 to 145 are turned on or off according to the values of on/off switching control signals <A> to <C>. More specifically, if, for example, on/off switching control signal <A>=“0”, the corresponding MOS transistor 143 is turned on. This also applies to on/off switching control signal <B> and on/off switching control signal <C>. If MOS transistors 140 to 142 are all in the off state, that is, on/off switching control signals <A> to <C> are all “0”, “0” data needs to be output from PAD and thus, MOS transistors 143 to 145 are all turned off.

Further, FIG. 8 is a conceptual diagram showing the on/off states of MOS transistors 140 to 142 when the output (“0” data, “1” data) of Dout₁ to Dout₁₆ is synchronous and the reading frequency of a clock signal is 104 MHz.

Also in FIG. 8, like in FIG. 7, data (“0” or “1”) that can be taken by on/off switching control signals <A> to <C> and the on/off states of MOS transistors 140 to 145 are shown. As described above, VHF=“1” and RM=“1” are set for synchronous reading at 104 MHz of a clock signal. If, in this state, the value of Dout₁ output from the latch circuit 120 is “1”, that is, high, MOS transistors 140 to 142 are all turned on and MOS transistors 143 to 145 are all turned off regardless of the values of on/off switching control signals <A> to <C>.

If the value of Dout₁ output from the latch circuit 120 is “0”, that is, low, MOS transistors 140 to 142 are all turned off and MOS transistors 143 to 145 are all turned on regardless of the values of on/off switching control signals <A> to <C>.

From the foregoing, if the reading frequency of a clock signal is 104 MHz and the values of VHF and RM in the register 61 are each “1”, the on/off state of the MOS transistor is made variable automatically depending on the signal level of Dout₁.

### <Effects According to the Present Embodiment>

In a memory system according to the present embodiment, faster data output from the data output buffer 93 is enabled by securing current supply capacity of the data output buffer 93. That is, in the present embodiment, the register 61 recognizes Config data supplied from a host device to the memory system 1. Accordingly, the memory system 1 recognizes the frequency of a clock signal and the values of VHF and RM in the Config data. That is, whether asynchronous reading or synchronous reading and the frequency of a clock signal is 66 MHz, 83 MHz, or further synchronous reading and burst reading at 104 MHz is indicated is determined.

In a memory system according to the present embodiment, if synchronous reading at 104 MHz of the frequency of a clock signal is recognized, the rate of rise of the voltage on node ADQ can be increased by setting all MOS transistors 140 to 142 to the on state and maximizing the current supply capacity regardless of the values of on/off switching control signals <A> to <C>. That is, the rise time is shortened and thus, the amount of data that can be transferred in the unit time can be increased. Accordingly, even if the clock signal supplied from a host device is, for example, at 104 MHz, Dout output from node ADQ can follow the frequency. That is, data output from the interface 90 to a host device can be made faster.

In a memory system according to the present embodiment, if reading is asynchronous reading or synchronous reading and the frequency of a clock signal is 66 MHz or 83 MHz, only one of MOS transistors 140 to 142 may be turned on. This is because even MOS transistor 140 with the smallest gate width has the current supply capacity to be able to follow the frequency of 83 MHz. In other words, the period from the rise to the fall of a voltage waveform of node ADQ can follow the frequency of a clock signal of 83 MHz.

Also in this case, the data output buffer 93 only needs to secure the necessary current supply capacity for data output. That is, noise can thereby be reduced.

If the reading frequency of a clock signal is 104 MHz and the memory system 1 can be made operable, that is, Dout can be output in synchronization with the clock signal without setting all MOS transistors 140 to 142 to the on state, only necessary transistors may be turned on. This case will be described below as the first modification.

### [First Modification]

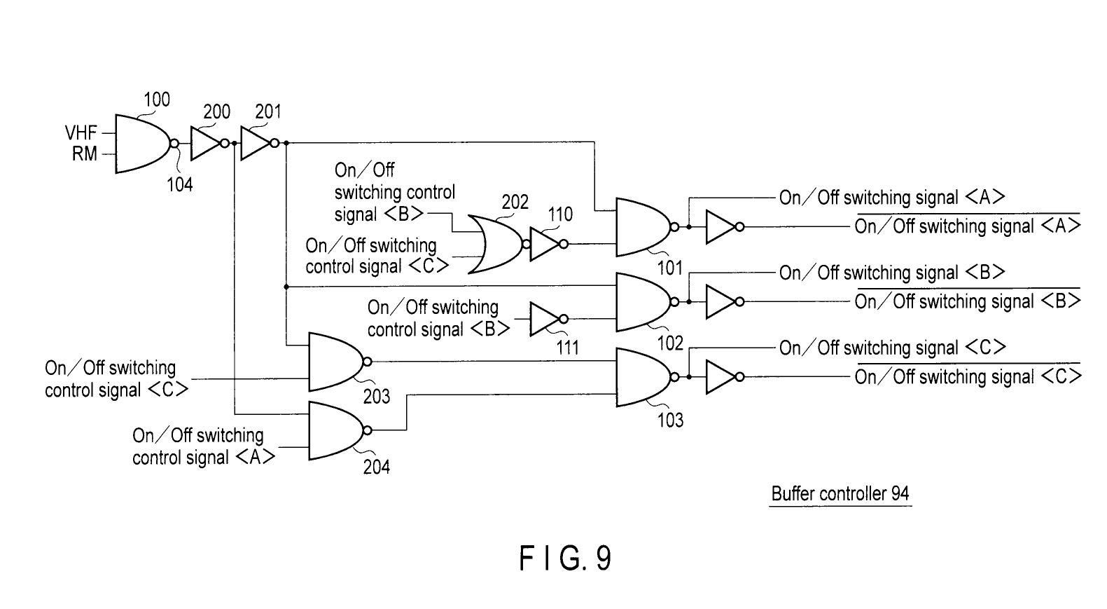

Next, a memory system according to the first modification of the above embodiment will be described below using FIGS. 9 to 11. Also in this modification, a memory system including a NAND flash memory and an SRAM can be cited as an example of the semiconductor storage apparatus. The description of the same configuration as that of the above embodiment is omitted and the same reference numerals are attached to elements of the same configuration.

While MOS transistors 140 to 142 are turned on to maximize the current supply capacity regardless of the values of on/off switching control signals <A> to <C> when VHF=1 and RM=1 in the above embodiment, the current supply capacity is decreased to reduce noise in the first modification. That is, even when VHF=1 and RM=1, MOS transistor 140 having the gate width Wc is turned off.

FIG. 9 shows a configuration example of the buffer controller 94 according to the first modification. As shown in FIG. 9, the buffer controller 94 according to the first modification has a configuration in which the inverters 112, 116 and the NOR gate 106 are removed from the buffer controller 94 according to the above embodiment and inverters 200, 201, a NOR gate 202, and NAND gates 203, 204 are newly added.

The inverter 200 inverts an operation result performed by NAND gate 100 and transfers the inverted result to NAND gate 204. The inverter 201 further inverts the signal supplied from the inverter 200 and transfers the inverted result to NAND gates 101, 102.

The NOR gate 202 performs a NOR operation of on/off switching control signal <B> and on/off switching control signal <C> and the inverter 110 inverts the operation result. The operation result from the NOR gate 202 inverted by the inverter 110 is transferred to one end of NAND gate 101. NAND gate 101 performs a NAND operation of operation results supplied from the inverters 201, 110 and transfers the operation result to the inverter 113.

NAND gate 102 performs a NAND operation based on signals supplied from the inverters 201, 111 and transfers the operation result to the inverter 114.

Further, NAND gate 203 performs a NAND operation of the operation result by the inverter 201 and on/off switching control signal <C> and transfers the operation result to NAND gate 103. NAND gate 204 transfers a NAND result of the operation result by the inverter 200 and on/off switching control signal <A> to NAND gate 103.

NAND gate 103 performs a NAND operation based on each operation result supplied from NAND gates 203, 204 and transfers the operation result to the inverter 115.

### <Operation of the Interface 90>

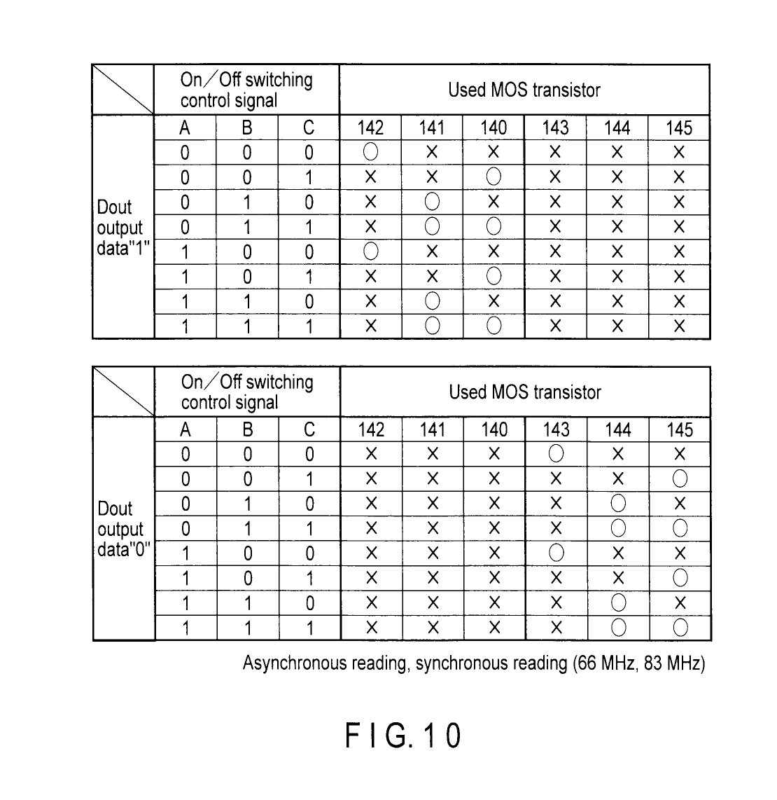

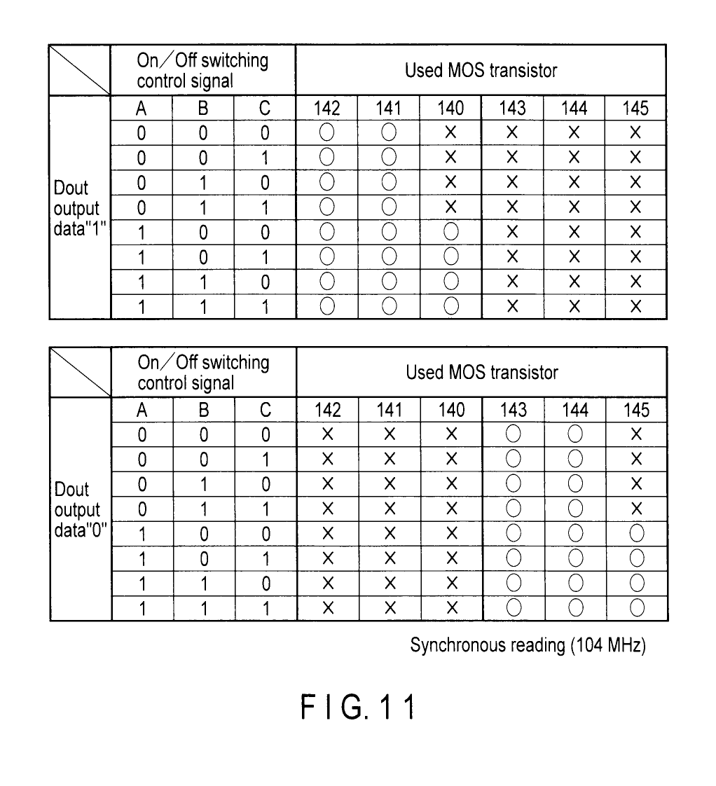

Next, the data output operation of the interface 90 according to the first modification will be described using FIGS. 10, 11. More specifically, FIGS. 10 and 11 are conceptual diagrams showing on/off operation of MOS transistors 140 to 145 operating based on on/off switching control signals <A> to <C> and control signals thereof. Like the above embodiment,

FIG. 10 shows a case when the output (“0” data, “1” data) of Dout₁ to Dout₁₆ is asynchronous or synchronous. That is, VHF and RM take one of the values of “0” and “1”. FIG. 11 shows a case when the output (“0” data, “1” data) of Dout₁ to Dout₁₆ is synchronous and the reading frequency of a clock signal is 104 MHz. That is, VHF and RM each take the value of “1”.

(1) When reading is asynchronous and the reading frequency is 66 MHz or 83 MHz (see FIG. 10)

A case when VHF=RM=0 and the value of Dout₁ is “1”, that is, high is cited as an example. In this case, MOS transistors 140 to 142 are each turned on or off according to the values of on/off switching control signals <A> to <C> and the configuration of the buffer controller 94 and MOS transistors 143 to 145 are turned off. The cases when VHF=0 and RM=1, and VHF=1 and RM=0 are similar to (1) described above and a description thereof is omitted. Also in these cases, like in FIG. 7, MOS transistors 143 to 145 are all turned off.

If the value of Dout₁ is “0”, that is, low, like in FIG. 7, MOS transistors 140 to 142 are all turned off regardless of the values of on/off switching control signals <A> to <C>. In accordance with the values of on/off switching control signals <A> to <C>, the corresponding MOS transistors 143 to 145 are turned on or off.

(2) When reading is synchronous and the reading frequency is 104 MHz (see FIG. 11)

That is, when VHF=RM=1, MOS transistor 140 is turned on or off according to the value of on/off switching control signal <A>. More specifically, if on/off switching control signal <A> is low (“0” in FIG. 11), on/off switching control signal <C> supplied to MOS transistor 140 is made low (“X” in FIG. 11), that is, the off state. This is because an operation result by NAND gates 203, 204 is operated by NAND gate 103. That is, NAND gates 103, 204 function as a selection unit to select On or Off of MOS transistor 140.

In contrast, NAND gates 101, 102, the NOR gate 202, and the inverters 110, 111 in FIG. 9 function as fixed circuits. That is, like the above embodiment, NAND gates 101, 102 output a high signal regardless of the values of on/off switching control signals <B>, <C> input into the NOR gate 202 and the inverter 111.

### <Effects According to the First Modification>

In a memory system according to the first modification, in addition to the above effects, noise can further be reduced when data is output and the area can further be reduced.

First, the reduction of noise will be described.

As described in the case of VHF=RM=1 in the first modification, noise on node ADQ can be reduced by decreasing the current supply capacity of the data output buffer 93 by using on/off switching control signal <A>. If the current supply capacity of the data output buffer 93 is increased too much, noise may be generated. Thus, in the first modification, generation of noise can be avoided by decreasing the current supply capacity. That is, the degree of freedom of the current supply capacity of the data output buffer 93 can be increased.

Next, the reduction of area will be described.

In a memory system according to the first modification, that is, when VHF=RM=1 and even the current supply capacity of the data output buffer 93 is made variable, like the above embodiment, MOS transistors 140 to 142 can be controlled only by on/off switching control signals <A> to <C>.

That is, for a data output buffer whose current supply capacity is variable as a comparative example, it is necessary to use, in addition to on/off switching control signals <A> to <C>, for example, on/off switching control signals <D> to <F> as signals to turn on or off MOS transistors 140 to 142. These on/off switching control signals <A> to <F> are assumed to be input into the gate of MOS transistors 140 to 142 denoted in the data output buffer 93 via a corresponding selection circuit.

More specifically, to control MOS transistor 142 as an example, it is necessary to use on/off control signals <A> and <D>. As a concrete configuration, one of on/off control signals <A> and <D> is connected to the gate of MOS transistor 142 via a selection circuit and a selection signal to select which of on/off switching control signals <A> and <D> to transfer to the gate of MOS transistor 142 is input into the selection circuit. Then, when MOS transistor 142 is turned on, on/off control signal <A> is provided to the gate thereof by the selection signal and when MOS transistor 142 is turned off, on/off control signal <D> is provided by the selection signal. This also applies to MOS transistors 141, 140. As a result, two control signals are needed for one transistor and a total of six control signals are needed. Like on/off switching control signals <A> to <C>, on/off switching control signals <D> to <F> are held in the management region in the memory cell array 10 of the NAND flash memory 2 and input into the data output buffer 93 after being temporarily held in a register. That is, a register that temporarily holds on/off switching control signals <D> to <F> to be input into the buffer controller 94 is further needed.

In contrast, when data is output from PAD at 104 MHz like in the first modification, the data output buffer 93 can be controlled only by on/off switching control signals <A> to <C> even when output noise is reduced. In the first modification, therefore, on/off switching control signals <D> to <F> are not needed and there is no need to increase the register.

### [Second Modification]

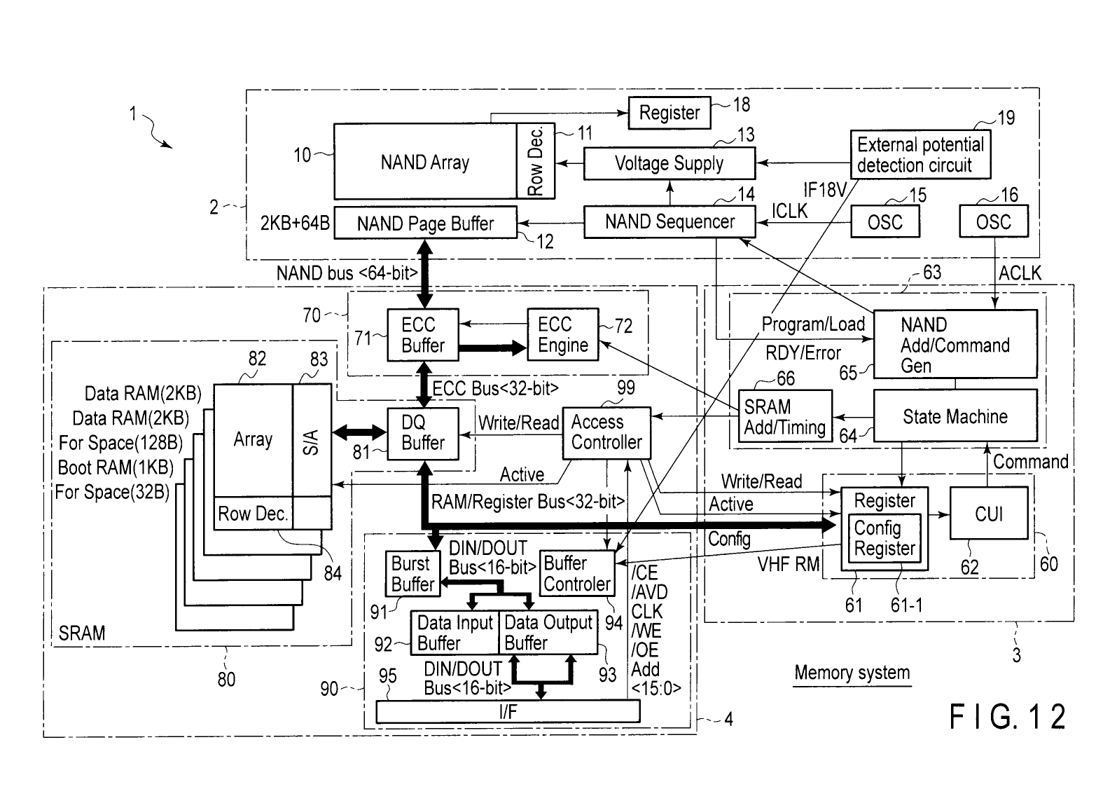

Next, a memory system according to the second modification of the above embodiment will be described below using FIGS. 12 to 15. Also in this modification, a memory system including a NAND flash memory and an SRAM can be cited as an example of the semiconductor storage apparatus. The description of the same configuration as that of the above embodiment is omitted and the same reference numerals are attached to elements of the same configuration.

While the current supply capacity of the data output buffer 93 is made variable in accordance with the frequency of a clock signal supplied from an external host device in the above embodiment, the current supply capacity of the data output buffer 93 is made variable in accordance with a rated voltage (V1, V2 (>V1)) supplied from the host device in the second modification. That is, when the rated voltage is V2, the current supply capacity in the data output buffer 93 is larger than when the voltage is V1 and thus, none of MOS transistors 140 to 142 is turned on.

When the rated voltage is V1, on the other hand, the current supply capacity is low and thus, all MOS transistors 140 to 142 can be turned on and the current supply capacity can be maximized and further, the current supply capacity to node ADQ can be decreased to reduce noise if necessary.

FIG. 12 shows an overall configuration example of the memory system 1 according to the second modification. As shown in FIG. 12, the memory system 1 according to the second modification further includes a detection circuit 19 (external potential detection circuit 19 in FIG. 12) to detect a voltage supplied from outside in the NAND flash memory 2. The detection circuit 19 detects which of voltage V1 (for example, 1.8 V) and voltage V2 (>V1) is the voltage supplied from outside. If the detection circuit 19 detects the supply of voltage V1, the detection circuit 19 supplies a signal IF18V=1 to the buffer controller 94. If the rated voltage is V2, the value of signal IF18V is set to “0”.

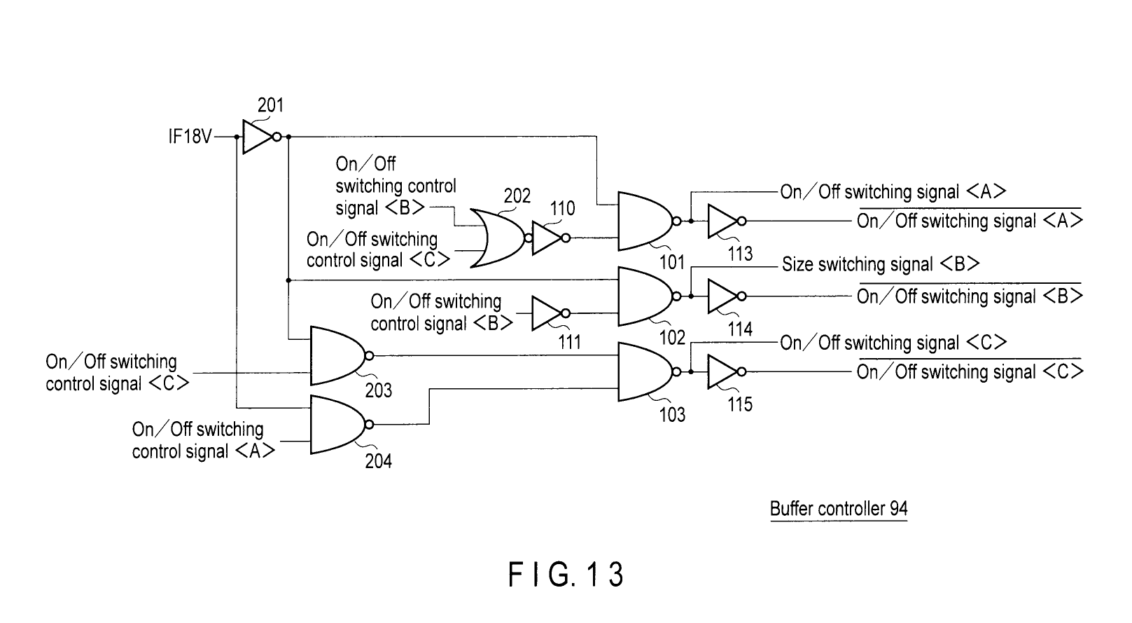

Next, a configuration example of the buffer controller 94 according to the second modification will be shown using FIG. 13. As shown in FIG. 13, the buffer controller 94 according to the second modification has a configuration in which NAND gate 100 and the inverter 200 are removed from the buffer controller 94 according to the first modification and signal IF18V is newly input into the inverter 201. That is, the current supply capacity of the output buffer 93 is made variable by using signal IF18V without using VHF and RM used in the above embodiment and the first modification.

### <Operation of the Interface 90>

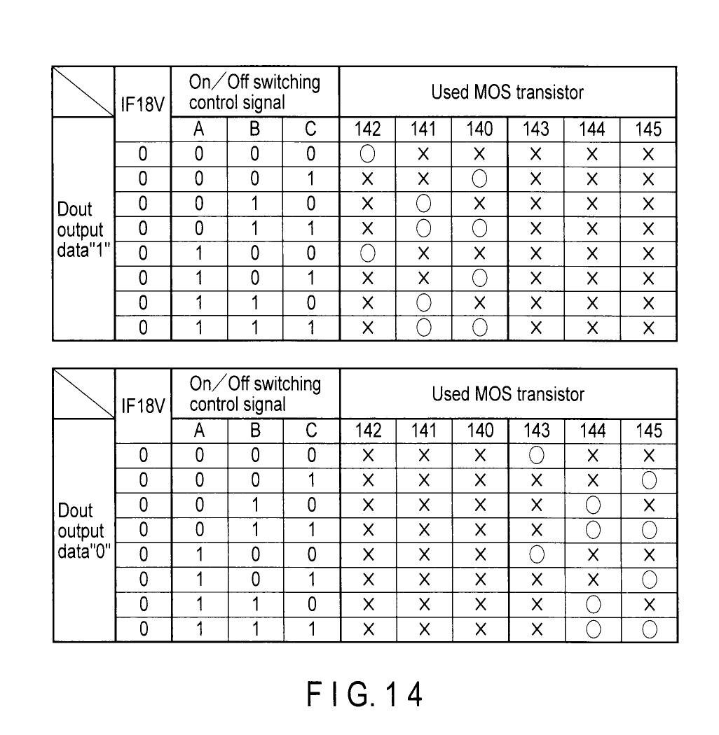

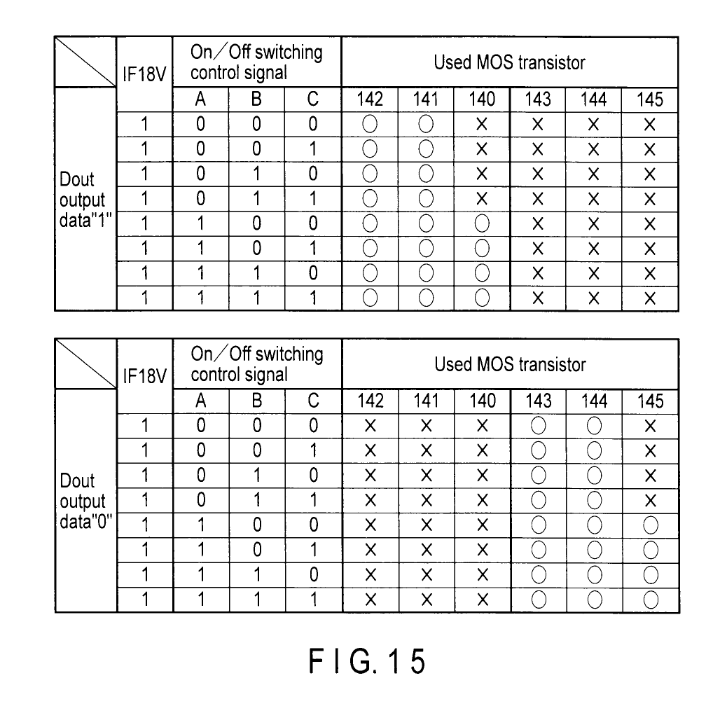

Next, the data output operation of the memory system 1 according to the second modification will be described using FIGS. 14, 15. More specifically, FIGS. 14 and 15 are conceptual diagrams showing on/off operation of MOS transistors 140 to 145 operating based on Dout₁, on/off switching control signals <A> to <C>, and control signals thereof. FIG. 14 shows a case when the value of Dout₁ is “0” or “1” and IF18V=0 and FIG. 15 shows a case when the value of Dout₁ is “0” or “1” and IF18V=1.

When the value of Dout₁ is “1” and IF18V=0, that is, the supply voltage from the host device is V2, as shown in FIG. 14, MOS transistors 140 to 145 are each turned on or off according to the values of on/off switching control signals <A> to <C>. That is, MOS transistors 140 to 142 are each turned on or off according to the configuration in FIG. 13 and the values of on/off switching control signals <A> to <C>.

In this case, the value of Dout₁ is “1” and thus, MOS transistors 143 to 145 are turned off regardless of the values of on/off switching control signals <A> to <C>.

On the other hand, if the value of Dout₁ is “0”, that is, low in FIG. 14, like in FIG. 7, MOS transistors 140 to 142 are all turned off regardless of the values of on/off switching control signals <A> to <C>. In accordance with the values of on/off switching control signals <A> to <C>, the corresponding MOS transistors 143 to 145 are turned on or off.

In contrast, when the value of Dout₁ is “1” and IF18V=1, that is, the supply voltage from the host device is V1, as shown in FIG. 15, the operation result of NAND gate 103 shown in FIG. 13 is a value in accordance with the value of on/off switching control signal <A>. If, as shown in FIG. 15, on/off switching control signal <A>=“1”, that is, high, the output of NAND gate 103 is made low and, as a result, MOS transistor 140 is set to, as illustrated in FIG. 15, the off state (“X” in FIG. 15). If on/off switching control signal <A>=“0”, that is, low, by contrast, the output of NAND gate 103 is made high and, as a result, MOS transistor 140 is set to, as illustrated in FIG. 15, the on state (“0” in FIG. 15).

If, in FIG. 15, the value of Dout₁ is “0” and IF18V=1, “0” data is output from node ADQ. Thus, MOS transistors 140 to 142 are all turned off (“X” in FIG. 15) regardless of the values of on/off switching control signals <A> to <C>. In contrast, MOS transistors 143 to 145 are each turned on or off according to the values of on/off switching control signals <A> to <C>.

### <Effects According to the Second Modification>

In a memory system according to the second modification, the current supply capacity of the data output buffer 93 can be made variable based on the value of voltage from a host device.

More specifically, when the rated voltage is V1, it is necessary to increase the current supply capacity by setting all MOS transistors 140 to 142 to the on state, but by increasing the current supply capacity, noise is generated when data is output from node ADQ. In this case, the current supply capacity of the data output buffer 93 is made variable in accordance with the value of on/off switching control signal <A> to reduce noise. That is, if noise should be reduced, MOS transistor 140 may be turned off by setting on/off switching control signal <A>=“0”. Thus, in a memory system according to the second modification, on/off switching control signal <A> can be caused to function as a control signal that automatically turns on or off MOS transistor 140 in accordance with the value of IF18V.

When IF18V=0, that is, the supply voltage from a host device is V2, the current supply capacity of the data output buffer 93 is increased too much and thus, as shown in FIG. 14, at least one of MOS transistors 140 to 142 may be turned on. Accordingly, noise when data is output can be reduced.

[Third Modification]

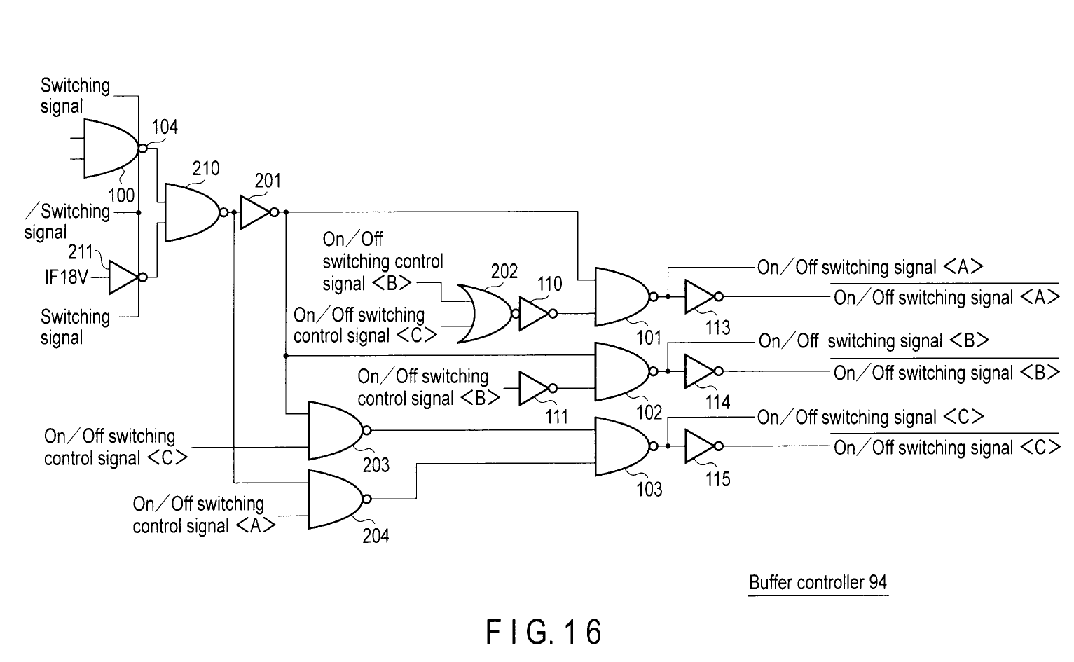

Next, a memory system according to the third modification of the above embodiment will be described below using FIG. 16. Also in the third modification, a memory system including a NAND flash memory and an SRAM can be cited as an example of the semiconductor storage apparatus. The description of the same configuration as that of the above embodiment is omitted and the same reference numerals are attached to elements of the same configuration. The third modification is a configuration that can select one of the first modification and the second modification.

FIG. 16 shows an overall configuration example of the buffer controller 94 according to the third modification. As described above, the configuration of the buffer controller 94 according to the third modification is a configuration that combines the first modification and the second modification and is provided with a switching signal to select one of the first modification and the second modification according to circumstances. As shown in FIG. 16, the buffer controller 94 according to the third modification includes a configuration in which a NAND gate 210 and an inverter 211 are newly provided in the buffer controller 94 according to the above embodiment to be able to switch the output of the inverter 211 and the output of NAND gate 100 by the switching signal.

As shown in FIG. 16, NAND gate 210 performs a NAND operation of an operation result by NAND gate 100 and an operation result of signal IF18V inverted by the inverter 211 and supplies the operation result to each of the inverter 201 and NAND gate 204. More specifically, if the value of the switching signal is “1”, IF18V is selected and if the value of the switching signal is “0”, the operation result of NAND gate 100 is selected. The content of operation in the third modification is the same as the content of operation described in the first modification and the second modification and thus, a description thereof is omitted.

### <Effects According to the Third Modification>

Even a memory system according to the third modification can achieve effects of the first modification or the second modification. That is, the buffer controller 94 according to the third modification can take the configuration of the first modification and the configuration of the second modification by a switching signal.

A semiconductor storage apparatus in the above embodiment and the first to third modifications is not limited to one NAND flash memory. That is, the configuration of the data output buffer 93 and the buffer controller 94 according to the above embodiment and the first to third modifications can also be applied to any memory element capable of holding data. The signal to be used by the data output buffer 93 and the buffer controller 94 may be any signal other than RM and VHF if the frequency of a clock signal from a host device can be recognized and the operation thereof is as described in the above embodiment and the first to third modifications.

In the present embodiment, the data output buffer 93 composed of the three MOS transistors 140 to 142 is shown as an example, but the present embodiment is not limited to this value. That is, in consideration of improving characteristics of the memory system 1 from the viewpoint of increasing the current supply capacity, the number of MOS transistors supplying the current to node ADQ may be four or more. In this case, the three on/off control signals <A> to <C> may be used for the control or more control signals may be used.

Further, in the present embodiment and the first to third modifications, frequencies of a clock signal are set to 66 MHz, 83 MHz, and 104 MHz, but the above configuration can also be applied when other frequencies exceeding the above frequencies are used. That is, even if the clock signal has a frequency of 104 MHz or more, the above configuration can also be applied as long as data can be output in synchronization with the clock signal.

In the present embodiment and the first to third modifications, the data output buffer 93 and the buffer controller 94 are controlled by using Config data or signal IF18V, but the memory system 1 may use other parameters as long as the data output buffer 93 and the buffer controller 94 can be controlled.

In the above embodiment and the first to third modifications, a case in which the memory system 1 is provided with the interface 90 capable of outputting data at high speed is shown, but the concept of the above embodiment and the first to third modifications can also be applied to the host side. That is, by providing the interface 90 also on the host side, the current supply capacity flowing into node ADQ applied to the host side can automatically be made variable. In this case, it is only necessary for the host to be able to determine the values of parameters (for example, VHF, RM) that make the current supply capacity variable in the interface 90 and it is only necessary to provide the detection circuit 19 in a host device so that the host device can use IF18V. When the detection circuit 19 is provided in the host device, the detection circuit 19 has a function to detect an external potential to supply a voltage to the host device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a NAND flash memory including memory cells capable of holding data and management data as a first control signal;
a first unit configured to hold a second control signal whose value is made variable depending on an output frequency of the data and a third control signal whose value is made variable depending on whether the data is output synchronously with the output frequency or asynchronously; and
an second unit configured to output the data read from the memory cells to an outside depending on the first to third control signals, wherein
the second unit
includes a buffer unit including first to third transistors,
the output frequency includes a first frequency and a second frequency higher than the first frequency, and
if the first to third transistors output the data to the outside in synchronization with the second frequency,
the first to third transistors may be turned on regardless of a value of the first control signal.

2. The system according to claim 1, wherein
the first control signal includes a first switching signal, a second switching signal, and a third switching signal which set the first to third transistors to the on state respectively,
if the first to third transistors output the data to the outside in synchronization with the first frequency,
at least one of the corresponding first to third transistors is turned on depending on the first to third switching signals.

3. The system according to claim 2, wherein
if the first to third transistors output the data to the outside in synchronization with the second frequency,
the first transistor is turned on or off in accordance with the first switching signal.

4. The system according to claim 3, wherein
the first transistor has a gate width of a first width, the second transistor has the gate width of a second width greater than the first width, and the third transistor has the gate width of a third width greater than the second width.

5. The system according to claim 1, wherein
the second unit
further includes an output controller including a logical unit which generates a second result as a fourth control signal, the second result being obtained from an operation with a first result and the first control signal, first result being obtained from an operation with the second control signal and the third control signal and,
the buffer unit sets the first to third transistors to the on state in depending on a third result obtained from the operation with the data and the fourth control signal.

6. The system according to claim 1, wherein
the data is output from one end of a current path of each of the first to third transistors.

7. The system according to claim 1, wherein
one end of a current path of the first to third transistors is connected to a common node from which the data is output and
the second unit includes
a fourth transistor whose one end is connected to the one end of the current path of the first transistor and whose other end is grounded,
a fifth transistor whose one end is connected to the one end of the current path of the second transistor and whose other end is grounded, and
a sixth transistor whose one end is connected to the one end of the current path of the third transistor and whose other end is grounded.

8. The system according to claim 7, wherein
When the data is output, the first transistor and the fourth transistor are not turned on simultaneously.

9. The system according to claim 5, wherein
the first control signal includes a first switching signal, a second switching signal, and a third switching signal which set the first to third transistors to the on state respectively, and the operation with the first result and the first control signal
is a logical operation of the first result, any one signal of the first switching signal, the second switching signal, and the third switching signal, and the second result obtained by the operation with the first switching signal, the second switching signal, and the third switching signal

10. The system according to claim 1, further comprising:
a detection circuit which detects one of external voltages of a first voltage and a second voltage higher than the first voltage and outputs a signal depending on the external voltage; and
a selection circuit which may select the second control signal, the third control signal, or the second control signal and the third control signal, or the signal.

11. A memory system comprising:
a NAND flash memory in which memory cells capable of holding data and management data as a first control signal are arranged in a matrix;
a first holding a second control signal whose value is made variable in accordance with an output frequency of the data and a third control signal whose value is made variable depending on whether the data is output synchronously with the output frequency or asynchronously; and
an second unit which outputs the data read from the memory cells to an outside in accordance with the first to third control signals, wherein
the second unit
includes a buffer unit including first to third transistors which each output the data to the outside in synchronization with the output frequency, the third transistor having a current supply capability lower than the current supply capability of the first and second transistors,
the output frequency includes a first frequency and a second frequency higher than the first frequency, and
the third transistor is turned off even if the output frequency is the second frequency.

12. The system according to claim 11, wherein
the first transistor has a gate width of a first width, the second transistor has the gate width of a second width greater than the first width, and the third transistor has the gate width of a third width greater than the second width.

13. The system according to claim 11, wherein
the first control signal includes a first switching signal, a second switching signal, and a third switching signal which set the first to third transistors to the on state respectively and
the off state of the third transistor is controlled by the third switching signal.

14. The system according to claim 13, wherein
the third switching signal
is obtained by an operation of
a first result obtained by an operation result of the third control signal which controls the third transistor and the first result obtained by the operation with the second control signal and the third control signal and
a second result obtained by the operation with the first control signal which controls the first transistor and the second control signal and the third control signal.

15. A memory system comprising:
a NAND flash memory in which memory cells capable of holding data and management data as a first control signal are arranged in a matrix;
a detection circuit which detects any one of external voltages of a first voltage and a second voltage higher than the first voltage; and
an second unit which outputs the data read from the memory cells to an outside in accordance with the external voltage and the first control signal, wherein
the second unit
includes a buffer unit including first to third transistors which each output the data to the outside and
whether the first to third transistors are controlled by the first control signal depends on one of the first voltage or the second voltage, and a value of the data.

16. The system according to claim 15, wherein
if the data is “1” and the external voltage is the second voltage,
On/Off of the first to third transistors are controlled by the first control signal.

17. The system according to claim 15, wherein
the first control signal includes a first switching signal to set the first transistor to the on state and
if the data is “1” and the external voltage is the first voltage,
On/Off of the third transistor is controlled by the first switching signal.

18. The system according to claim 5, wherein
The first control signal includes fifth control signal, sixth control signal, and seventh control signal, and
the logical unit comprises:
a first logical circuit outputting the first result;
a second logical circuit operating the fifth control signal to the seventh control signal and outputting fourth result, and
a third logical circuit operating with any one signal of the fifth control signal to the seventh control signal, the first result, and the fourth result and outputting a fifth result.

19. The system according to claim 10, wherein
The first control signal includes fifth control signal, sixth control signal, and seventh control signal, and
the buffer comprises:
a fourth logical circuit operating with the signal depending on the external voltage and a sixth result being obtained from an operation with the sixth control signal and the seventh control signal, and outputting a seventh result,
a fifth logical circuit operating with the signal depending on the external voltage and the sixth result, and outputting an eighth result, and
a sixth logical circuit operating with the signal depending on the external voltage, the fifth control signal and the seventh control signal, and outputting ninth result.
